(19) United States
(12) Patent Application Publication
(10) Pub. No.: US 2005/0237802 A1
(43) Pub. Date: Oct. 27, 2005

(54) Device for controlling electric actuators, with automatic current measurement offset compensation, and relative operation method

(76) Inventors: Paolo Santero, Orbassano (IT); Alberto Manzone, Orbassano (IT); Riccardo Groppo, Orbassano (IT)

Correspondence Address: STERNE, KESSLER, GOLDSTEIN & FOX PLLC, 1100 NEW YORK AVENUE, N.W., WASHINGTON, DC, 20005, US

(21) Appl. No.: 11/109,687

(22) Filed: Apr. 20, 2005

(30) Foreign Application Priority Data
Apr. 21, 2004 (EP) 04425277.3

(51) Int. Cl. G11C 16/04

(52) U.S. Cl. 365/185.11

(57) ABSTRACT

An electric actuator control device designed to automatically compensate the total current measurement offset introduced by the various stages in a measuring block, so as to improve current measurement precision and to optimize operation control of the electric actuators. A method of automatically compensating the current measurement offset of an electric actuator control device, and a device for controlling electric actuators, with automatic current measurement offset compensation.

The present invention relates to a device for controlling electric actuators, with automatic current measurement offset compensation, and to the relative operation method.

The present invention may be used to particular advantage, though not exclusively, for controlling solenoid valves controlling intake and exhaust of an automotive internal combustion engine, or for controlling other types of electric actuators, such as solenoid valves of ABS devices and similar, electronic injectors, etc.

As is known, electric actuator control devices typically comprise a power circuit having a number of power blocks, each for supplying current to a corresponding electric actuator; and a driver circuit for controlling operation of the power blocks to regulate current supply to each electric actuator according to a predetermined time pattern.

To do this, the driver circuit comprises a measuring stage connected to the power circuit to determine, instant by instant, the current supplied by each power block to the respective electric actuator; and a control stage, which drives the power blocks to control current supply to the electric actuators, and cooperates with the measuring stage to supply the electric actuator with the desired current.

More specifically, the measuring stage comprises a number of measuring blocks, each of which measures, at each instant, the value of the current flowing through a respective power block, i.e. flowing through the electric actuator, and supplies the control stage with a comparison signal indicating the measured current has reached a current threshold set by the control stage. In other words, by means of each measuring block, the control stage provides for closed-loop current control, in which the current flowing in the electric actuator is regulated not only by the control algorithm, but also according to its measured value.

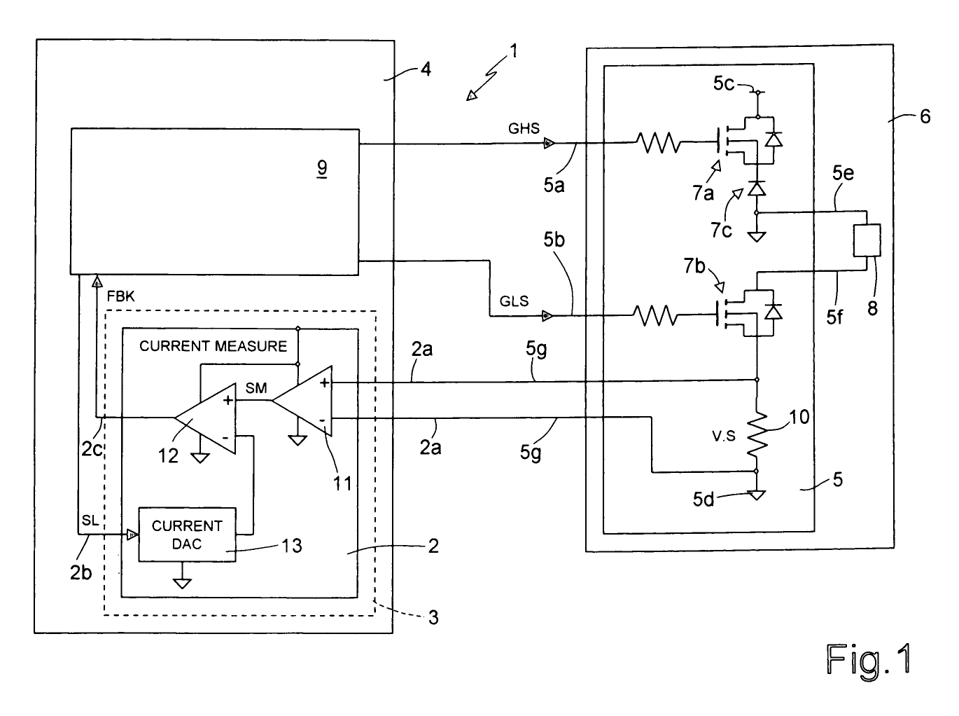

By way of example, FIG. 1 shows, schematically, a number of components of a currently used control device 1, and, in particular, one of the measuring blocks 2 of the measuring stage 3 forming part of a driver circuit 4, and one of the power blocks 5 supplying current to an electric actuator forming part of the power circuit 6.

In FIG. 1, power block 5 has two input terminals 5a, 5b connected to two terminals of the control stage 9 to receive a control signal GHS and a control signal GLS respectively; two supply terminals 5c, 5d connected to a supply line and a ground line respectively; and two output terminals 5e, 5f, between which is connected an electric actuator 8.

More specifically, power block 5 comprises a controlled switch 7a connected between terminals 5c and 5e to regulate current flow in electric actuator 8 as a function of the control signal GHS from control stage 9; a controlled switch 7b connected between terminals 5f and 5d to regulate current flow in electric actuator 8 as a function of the control signal GLS from control stage 9; and a recirculating diode 7c with the anode connected to ground terminal 5d, and the cathode connected to output terminal 5e. Diode 7c may be replaced with a third controlled switch acting as a synchronous rectifier.

Power block 5 also comprises a sense stage defined by a sense resistor 10 interposed between controlled switch 7b and ground terminal 5d, and has two output terminals 5g connected to the terminals of sense resistor 10 to supply a measuring voltage Vₛ proportional to the current flow in sense resistor 10.

Measuring block 2 comprises a first and a second input terminal 2a connected to respective output terminals 5g of power block 5 to receive measuring voltage Vₛ; a third input terminal 2b supplied by control stage 9 with a signal indicating a current limit threshold SL corresponding, as stated, to the current value to be reached in electric actuator 8 as a result of the commands imparted by control stage 9; and an output terminal 2c connected to and supplying control stage 9 with a comparison signal FBK.

More specifically, measuring block 2 sets comparison signal FBK to a first logic level when the measured current value exceeds limit threshold SL set by control stage 9, and to a second logic level when the measured current value is below limit threshold SL.

In its simplest form, measuring block 2 comprises an amplifying stage 11 defined by a typically differential amplifier; a comparing stage 12 defined by a comparator; and a generating stage 13 which generates threshold voltage SL and is typically defined by a digital/analog converter.

Amplifying stage 11 has two inputs connected to the two input terminals 2a of measuring block 2 to receive measuring voltage Vₛ, and an output supplying a measurement signal SM indicating a voltage value related to the measured current; and comparing stage 12 has one input connected to and receiving measurement signal SM from the output of amplifying stage 11, another input connected to the output of the generating stage to receive limit threshold SL, and an output connected to output terminal 2c to supply comparing signal FBK to control stage 9.

During operation of control device 1, control stage 9 implements an electric actuator control algorithm to determine, instant by instant, the value of the current supplied to each electric actuator, and accordingly generates control signals GHS and GLS for supply to controlled switches 7a and 7b of the controlled power block 5.

Simultaneously with control of power block 5, control stage 9 assigns an appropriate current value to limit threshold SL, which is coded into a digital signal and supplied to generating stage 13, which provides for digital-analog conversion of the signal for supply to comparing stage 12.

Amplifying stage 11 of measuring block 2 picks up measuring voltage Vₛ at the terminals of sense resistor 10, and supplies comparing stage 12 with measurement signal SM, which is compared with limit threshold SL by comparing stage 12, which accordingly generates comparison signal FBK for supply to control stage 9.

On receiving comparison signal FBK, control stage 9 is able to determine whether or not the current flow in electric actuator 8 has reached limit threshold SL, and accordingly controls power block 5.

The current detecting method of measuring blocks 2 described above has the major drawback of involving a current measurement error, i.e. offset, preventing optimum control of the electric actuators. Stages 11, 12 and 13 integrated in measuring blocks 2, in fact, each introduce a current measurement error, i.e. offset, thus impairing the accuracy with which the current in the electric actuator is controlled by control stage 9.

It is an object of the present invention to provide an electric actuator control device designed to automatically compensate the total current measurement offset introduced by the various stages in each measuring block, so as to improve current measurement precision and so optimize operation control of the electric actuators.

According to the present invention, there is provided a method of automatically compensating the current measurement offset of an electric actuator control device, as claimed in claim 1.

According to the present invention, there is also provided a device for controlling electric actuators, with automatic current measurement offset compensation, as claimed in claim 7.

A preferred, non-limiting embodiment of the present invention will be described by way of example with reference to the accompanying drawings, in which:

FIG. 1 shows a circuit diagram of a number of component parts of a known electric actuator control device;

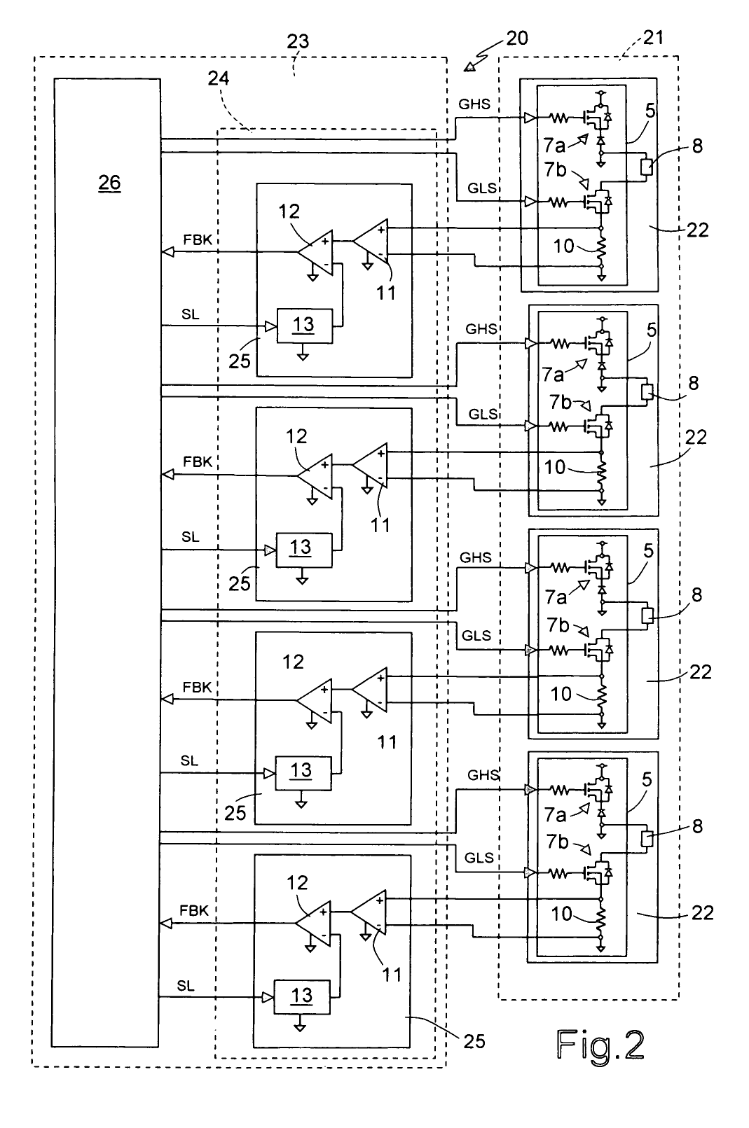

FIG. 2 shows a circuit diagram of an electric actuator control device, with automatic offset compensation, in accordance with the teachings of the present invention;

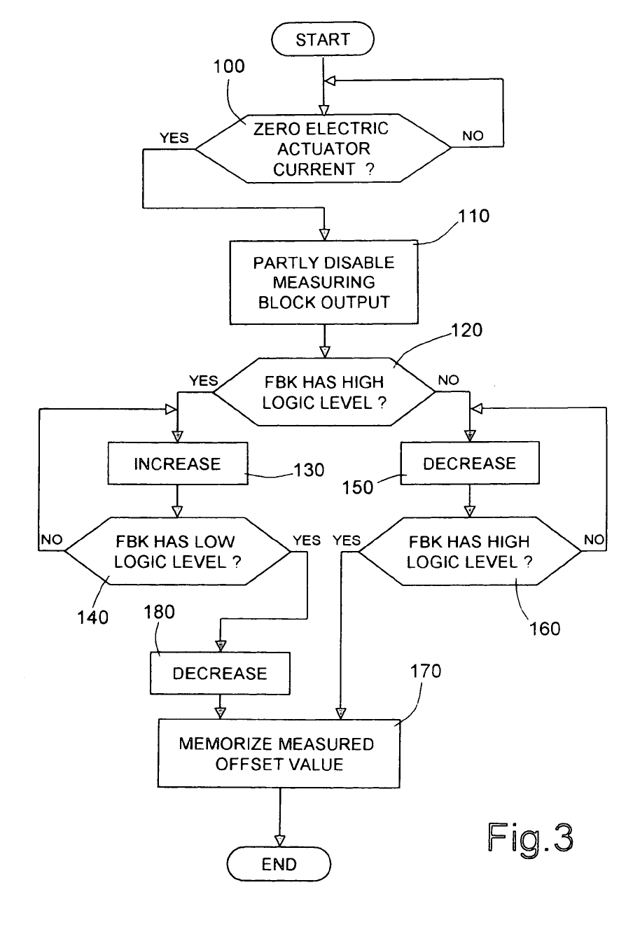

FIG. 3 shows a flow chart of the operations performed by the electric actuator control device to automatically compensate the offset.

Number 20 in FIG. 2 indicates as a whole a device for controlling electric actuators, and which, unlike known electric actuator control devices, implements a method of automatically compensating the current measurement offsets introduced in the various measuring blocks (forming part of the control device).

Electric actuator control device 20 substantially comprises a power circuit 21 having a number of power blocks 22 (four shown in FIG. 2), each for supplying current to a corresponding electric actuator; and a driver circuit 23 for controlling power blocks 22 to regulate current supply to each electric actuator according to a predetermined time pattern.

More specifically, each power block 22 receives two control signals GHS, GLS, as a function of which power block 22 regulates current supply to the relative electric actuator, and supplies a measuring voltage Vₛ related to the current flow in the electric actuator. In the example shown, each power block 22 is the same as in FIG. 1, so the component parts are indicated using the same reference numbers with no further description.

Driver circuit 23 comprises a control stage 26 supplying control signals GHS and GLS to power blocks 22 to regulate the current in the electric actuators; and a measuring stage 24 for measuring in each power block 22 the value of the current flow in the electric actuator.

More specifically, measuring stage 24 comprises a number of measuring blocks 25, each for comparing the measured current value and a limit threshold SL indicating the current level to be reached in the controlled electric actuator as a result of the command imparted by control stage 26.

Each measuring block 25 supplies a comparison signal FBK indicating the current flowing in the electric actuator has reached the current value corresponding to the value of limit threshold SL established by control stage 26.

In the example shown, comparison signal FBK has a first logic level when the measured current value is substantially above limit threshold SL; and a second logic level when the measured current value is substantially below limit threshold SL.

Each measuring block 25 is the same as in FIG. 1, so the component parts are indicated using the same reference numbers with no further description.

Besides implementing a known electric actuator operation control algorithm enabling it to determine and control current supply to each electric actuator at a given instant, control stage 26 also implements a method of compensating the current measurement offsets introduced by the various measuring blocks 25 during current control.

More specifically, according to the compensation strategy, which will be described in detail later on, control stage 26, in cooperation with each measuring block 25, determines the current measurement offset value introduced in the measuring block 25, and memorizes the offset value in a special memory register REGOF forming part of control stage 26. In the example shown, the current offset value of each measuring block 25 is added automatically in control stage 26 to the desired current limit threshold, and the result is the actual value of limit threshold SL supplied by control stage 26 to measuring block 25, thus conveniently zeroing the offset error in comparison signal FBK.

FIG. 3 shows a flow chart of the operations performed in the current measurement offset compensation method. As these are the same for compensating the offset in each of measuring blocks 25, reference is made below, for the sake of simplicity, to determining and memorizing the measured current offset of one measuring block 25 only.

Control stage 26 activates the compensation method when a rest condition of the electric actuator is determined, i.e. when current flow in the electric actuator is zero (block 100). This condition can obviously be determined directly by control stage 26, by virtue of it directly controlling power block 22.

When implementing the offset determination and compensation strategy, control stage 26 disables closed-loop control of power block 22, i.e. disables acquisition of comparison signal FBK for controlling the current of the electric actuator, so as to conveniently eliminate the effect of any compensation strategy signals which may impair control of the electric actuator. In other words, when implementing the present method, the comparison signal FBK supplied by comparing stage 12 is only used by control stage 26 to measure the offset of measuring block 25, and not for direct control of power block 22 (block 110).

At this step, control stage 26 initially enters in register REGOF an initial offset value corresponding, for example, to a zero current value, and assigns this value to current limit threshold SL.

Once the value is assigned, control stage 26 supplies current limit threshold SL to generating stage 13, which converts it to the appropriate format and in turn supplies it to comparing stage 12. At this step, amplifying stage 11 picks up a zero voltage Vₛ (being measured at the terminals of sense resistor 10 which, at this step, has substantially no current flow), and supplies measurement signal SM to comparing stage 12, the other input of which receives limit threshold SL from generating device 13. Comparing stage 12 then compares the two inputs and, depending on the signals at them, supplies comparison signal FBK.

Control stage 26 receives comparison signal FBK (block 120) and, depending on the logic level of the comparison signal, increases or decreases the value memorized previously in register REGOF. This operation is repeated cyclically until a switch in comparison signal FBK is detected.

In the example shown, if comparison signal FBK has a first, e.g. high, logic level (corresponding to a condition in which measurement signal SM is above the value corresponding to limit threshold SL), then the offset initially memorized in register REGOF is less than the real offset in measuring block 25 (YES output of block 120); and conversely, if comparison signal FBK has a second, e.g. low, logic level (corresponding to a condition in which measurement signal SM is below the value corresponding to limit threshold SL), then the offset value memorized in register REGOF is greater than the real offset in measuring block 25 (NO output of block 120).

In the first case, i.e. if comparison signal FBK has a high logic level, control stage 26 cyclically increases the offset value memorized in register REGOF as long as comparison signal FBK remains unchanged. That is, at each cycle at this step, control stage 26 increases the offset memorized in register REGOF by a predetermined value (block 130), and assigns the updated value to current limit threshold SL, which is converted and supplied to comparing stage 12, which compares it with measurement signal SM and supplies comparison signal FBK. Control stage 26 then determines whether comparison signal FBK from measuring block 25 has switched or not, i.e. changed logic level (block 140).

If it has not, i.e. if comparison signal FBK remains unchanged (NO output of block 140), control stage 26 repeats the cycle, again increasing the offset value memorized in register REGOF by a predetermined value (block 130), assigning the updated offset value to limit threshold SL, and again comparing limit threshold SL and measurement signal SM to determine the logic level of comparison signal FBK (block 140).

Conversely, i.e. if comparison signal FBK has changed logic level (YES output of block 140), control stage 26 ends the measuring procedure: the value memorized in register REGOF is decreased by a predetermined value (block 180), and the result, which corresponds to the real current measurement offset of measuring block 25, is memorized again in register REGOF (block 170).

Conversely, in the second case, i.e. if, in the initial comparison (block 120), comparison signal FBK has a second, e.g. low, logic level (corresponding to a condition in which measurement signal SM is below the value corresponding to limit threshold SL), control stage 26 cyclically decreases the offset value memorized in register REGOF until comparison signal FBK switches from its initial logic level.

That is, at each cycle at this step, control stage 26 decreases the offset memorized in register REGOF by a predetermined value (block 150), and assigns the updated value to current limit threshold SL, which is converted and supplied to comparing stage 12, which compares it with measurement signal SM and supplies comparison signal FBK. Control stage 26 then determines whether or not comparison signal FBK has switched, i.e. changed logic level (block 160).

If it has not, i.e. if comparison signal FBK remains unchanged (NO output of block 160), control stage 26 again decreases the current offset value memorized in register REGOF by a predetermined value, assigns the updated offset value to limit threshold SL, again compares limit threshold SL and measurement signal SM, and again checks the logic level of comparison signal FBK (block 160).

Conversely, i.e. if comparison signal FBK has switched logic level (YES output of block 160), control stage 26 ends the measuring procedure, and the value memorized in register REGOF corresponds to the real offset of measuring block 25 (block 170).

At this point, the value memorized in register REGOF is used by control stage 26 for normal closed-loop control of the electric actuator, to compensate the real offset introduced by the measuring block. More specifically, during control, control stage 26 uses the offset memorized in register REGOF to correct limit threshold SL (used each time as a threshold for comparison with the current measured in the power block). To make the correction, control stage 26, during control, adds the offset memorized in register REGOF to limit threshold SL, thus automatically compensating the real offset introduced in measuring block 25.

The current measurement offset value memorized in register REGOF is used to compensate the offset until the control stage again performs the offset determination procedure, and the updated offset value is entered into register REGOF. This therefore provides for also compensating offsets varying slowly with time.

The electric actuator control device has the big advantage of automatically compensating the total current measurement offset introduced by each measuring block, thus ensuring highly accurate current measurement and, hence, optimum operation control of the electric actuators, with no need for any additional electronic components or devices.

1. An automatic offset compensation method for automatically compensating the current measurement offset of a device for controlling electric actuators and including at least one power block for supplying current to a respective electric actuator; and a driver circuit in turn including a control stage for controlling operation of said power block, and at least one measuring block having at least a first input receiving a first signal whose value is related to the current measured in said power block, a second input receiving a second signal whose value is related to a predetermined current threshold, and an output supplying said control stage with a comparison signal having a first or a second logic level, depending on the outcome of a comparison of said first and second signal; said method comprising the steps of:
(a) assigning to said first and said second signal a first and a second predetermined value respectively;
(b) checking that the initial logic level of said comparison signal satisfies a first predetermined condition;
(c) making, on the basis of the outcome of said check, a number of increases or decreases to the second value of the second signal as long as the logic level of said comparison signal remains unchanged;
(d) on determining a switch in the logic level of the comparison signal, assigning to a current measurement offset value a value related to the second value of said second signal which has produced the switch in the logic level of the comparison signal.

2. An automatic offset compensation method as claimed in claim 1, further comprising the step of correcting, as a function of said current measurement offset value, the value of said current threshold to be assigned to said second signal when measuring the current in said power block.

3. An automatic offset compensation method as claimed in claim 1 wherein said step of making a number of incresases or decreases to the second value comprises increasing said second value by a predetermined value when said comparison signal has the first logic level; or decreasing said second value by a predetermined value when said comparison signal has the second logic level.

4. An automatic offset compensation method as claimed in claim 1, wherein said step of assigning a value to a current measurement offset value further comprises memorizing said second value in a memory register.

5. An automatic offset compensation method as claimed in claim 1, wherein said step of assigning a predetermined value to said first and said second signal further comprises the step of assigning a substantially zero value to said first value of said first signal.

6. An automatic offset compensation method as claimed in claim 1, wherein said step of assigning a predetermined value to said first and said second signal further comprises the step of determining a zero current condition in said power block, and of assigning to said first value the value of an electric quantity related to the determined zero current condition.

7) A device for controlling electric actuators, with automatic offset compensation, and including at least one power block for supplying current to a respective electric actuator; and a driver circuit in turn including a control stage for controlling operation of said power block, and at least one measuring block having at least a first input receiving a first signal whose value is related to the current measured in said power block, a second input receiving a second signal whose value is related to a predetermined current threshold, and an output supplying said control stage with a comparison signal having a first or a second logic level, depending on the outcome of a comparison of said first and second signal; said device comprising:
control means for assigning to said first and said second signal a first and a second predetermined value respectively;
first comparing means for checking that the initial logic level of said comparison signal satisfies a first predetermined condition;
second comparing means for making, on the basis of the outcome of said check, a number of increases or decreases to the second value as long as the logic level of said comparison signal remains unchanged;
storage means which, upon a switch in the logic level of the comparison signal, assigns a value related to the second value of said second signal to a current measurement offset value relative to said measuring block, and memorizes said current measurement offset value in a memory register.

8. A device for controlling electric actuators, as claimed in claim 7, further comprising compensating means for compensating the offset of said measuring block, and for correcting, as a function of said current measurement offset value, the value of said current threshold to be assigned to said second signal when measuring the current in said power block.

9. A device for controlling electric actuators, as claimed in claim 7, wherein said second comparing means comprises first variation means for increasing said second value by a predetermined value when said comparison signal has the first logic level; and second variation means for decreasing said second value by a predetermined value when said comparison signal has the second logic level.

10. A device for controlling electric actuators, as claimed in claim 7, wherein said measuring block comprises an amplifying stage for receiving said first signal and supplying a measurement signal; a generating stage for receiving said second signal and supplying it in a predetermined format; and a comparing stage for comparing said measurement signal and said second signal, and for supplying said comparison signal.

11. A device for controlling electric actuators, with automatic offset compensation, comprising:
at least one power block for supplying current to a respective electric actuator;
a controller for controlling operation of said power block, wherein said controller includes a first output for supplying a threshold signal;
a first comparator having a first input receiving a power current signal related to a current measured in said power block, a second input receiving said threshold signal from said first output of said controller, and an output supplying said controller with a comparison signal having a first or a second logic level, depending on the outcome of a comparison of said power current signal and said threshold signal;
a disabling mechanism for disabling direct control of the power block such that said power current signal relates only to an offset when said disabling mechanism is operated;
a second comparator for making, on the basis of said comparison signal, a number of increases or a number of decreases to the threshold signal as long as the logic level of said comparison signal remains unchanged when said disabling mechanism is operated; and
a memory register which, upon a switch in the logic level of the comparison signal when said disabling mechanism is operated, stores a current measurement offset value related said threshold signal.

12. A device for controlling electric actuators, as claimed in claim 11, further comprising a compensator for correcting said threshold signal by the addition of said current offset value when said disabling mechanism is not operated.

13. A device for controlling electric actuators as claimed in claim 11, wherein said second comparator increases or decreases said threshold signal by a predetermined value.

14. A device for controlling electric actuators as claimed in claim 11, further comprising:
an amplifier for receiving as input said power current signal and supplying as output a measurement signal; and
a generator for receiving as input said threshold signal and supplying as output said threshold signal to said first comparator in a predetermined format.

15. A device for controlling electric actuators as claimed in claim 14, wherein said generator is a digital to analog converter.

16. A device for controlling electric actuators as claimed in claim 11, wherein said cotnroller includes a second output for supplying a control signal to said power block.

17. A device for controlling electric actuators as claimed in claim 16, further comprising a plurality of first comparators and a plurality of power blocks coupled to a single controller via a plurality of first and second outputs, respectively.

18. A device for controlling electric actuators as claimed in claim 17, further comprising a plurality of memory registers coupled to said single controller.
